(19) United States
(12) Patent Application Publication
(10) Pub. No.: US 2026/0163568 A1
(43) Pub. Date: Jun. 11, 2026

(54) METHOD FOR DRIVING A CIRCUIT ARRANGEMENT FOR POWER SEMICONDUCTORS

(71) Applicant: ZF Friedrichshafen AG, Friedrichshafen (DE)

(72) Inventors: Illia Manushyn, Pegnitz (DE); Steffen Heider, Pegnitz (DE); Johannes Hager, Marktleugast (DE)

(73) Assignee: ZF Friedrichshafen AG, Friedrichshafen (DE)

(21) Appl. No.: 19/414,815

(22) Filed: Dec. 10, 2025

(30) Foreign Application Priority Data
Dec. 11, 2024 (DE) 10 2024 211 770.6

(51) Int. Cl. H03K 17/296; H03K 17/16

(52) U.S. Cl. CPC H03K 17/296; H03K 17/162; H03K 2217/0063; H03K 2217/0072

(57) ABSTRACT

A method for controlling a circuit assembly for power semiconductors in an inverter that has at least one phase, containing at least two switches that are complementary to each other and which are activated alternatingly in a switching process, wherein an on-pulse is applied to the complementary switch for a predefined period of time at a predefined time after starting a switching process for the active switch.

### CROSS-REFERENCE TO RELATED APPLICATION

This application claims priority to German Patent Application No. 10 2024 211 770.6, filed on Dec. 11, 2024, the entirety of which is hereby fully incorporated by reference herein.

### TECHNICAL FIELD

The present disclosure relates to the field of electric vehicles, specifically the electronics modules for an electric drive.

### BACKGROUND

Power electronics systems are used worldwide for numerous things, including drives, producing electricity, charging devices, inductive power transmission systems, high voltage direct current transmission lines, aircraft power supply systems, electric vehicles and switching power supplies. One of the main challenges with power electronics systems is the electromagnetic contamination with high-frequency interferences they generate. The high level of electromagnetic interference generated by power electronics converters can impact adjacent electrical systems and disrupt radio service. To address this problem, the undesired interferences must be limited to a certain extent.

The main sources of electromagnetic interference in power electronics systems are power semiconductor switches (also referred to as simply power semiconductors). A broad band spectrum of interferences are emitted during the power semiconductor switching process. Faster switching of the power semiconductors results in greater interferences. It is nevertheless also the goal to bring the power semiconductors to the limit of their switching speeds to minimize losses in the system and consequently increase the efficiency thereof. Consequently, the interferences must be eliminated with other means.

A conventional approach to minimize electromagnetic emissions is to use passive electromagnetic compatibility filters (EMC filters). EMC filters can form modules that are subsequently incorporated in inverters, or integrated in other modules in the commutation cells or printed circuit boards. By way of example, Y capacitors can be incorporated in the direct current intermediate capacitors to improve their thermal behavior. A magnetic core can also be used directly on the phase interface instead of a normal DC common mode inductor. Whether an EMC filter is produced as a module or EMC suppression components are integrated separately in the inverter, there are usually disadvantages such as higher component and production costs, as well as an increase in size and weight. Furthermore, interferences generated by the switching edges or oscillations after the switching process, are hardly damped with a passive EMC filter, because the behavior of passive components is determined by the parasites.

A fundamental object of the present disclosure is to create a method for damping oscillations occurring after switching power semiconductor switches.

This is achieved by the features disclosed herein. Advantageous designs are also the subject matter of the present disclosure.

### SUMMARY

The present disclosure results in a method for controlling a circuit assembly for power semiconductors in an inverter with at least one phase, which has complementary switches that are activated alternatingly in a switching process, in which an on-pulse is applied to the complementary switch for a predefined time period at a predetermined time after starting the switching process for the active switch.

In various embodiments, the time at which the on-pulse is emitted is selected such that the earliest that this occurs is a time at which high-frequency oscillations occur in the voltage and the current of the active switch due to the switching process.

In various embodiments, the time at which the on-pulse is applied to the complementary switch is 100 ns or more after starting the switching process.

The length of the on-pulse can be selected such that the complementary switch does not become fully saturated.

The length of the on-pulse may range from 50 ns to 400 ns.

A computer program is also disclosed that executes the method and can be executed on a control unit in the vehicle.

A circuit assembly is also disclosed that contains at least one high-side switch and one low-side switch, each of which has at least one transistor, which is part of an inverter in an electronics module for controlling the electric drive of an electric vehicle, and which is controlled by the method described herein.

The present disclosure also relates to an electric drive for a vehicle, which contains an electronics module for controlling the electric drive that contains an inverter with the circuit assembly described herein.

A control unit is also disclosed with which a circuit assembly that contains at least one high-side switch and one low-side switch, each of which has at least one transistor, can be controlled using the method described herein.

A vehicle with this electric drive is also disclosed.

Other features and advantages of the present disclosure can be derived from the following description of exemplary embodiments of the present disclosure, the drawings showing details of the present disclosure, and the claims. The individual features can be used in and of themselves or in various combinations forming variations of the present disclosure.

Preferred embodiments of the present disclosure shall be explained in greater detail below in reference to the drawings.

### BRIEF DESCRIPTION OF THE DRAWINGS

FIG. 1 shows an example of the gate voltage curves over time for an active switch and a complementary switch, which are operated according to the method obtained with the present disclosure.

FIG. 2 shows an example of the drain current over time for an active switch that is operated according to the method obtained with the present disclosure.

### DETAILED DESCRIPTION

Identical elements and functions have the same reference symbols in the following descriptions of the drawings.

As stated above, an aim of the present disclosure is the damping of high-frequency oscillations resulting from switching power semiconductor switches (hereinafter referred to as switches). The oscillations occur in the switching process because the commutation circuit contains parasitic components such as leakage inductances that oscillate with the output capacity of the switch that is off. Oscillations are generated by interactions of the components in the commutation circuit. These high-frequency oscillations can occur when switching the switches on or off.

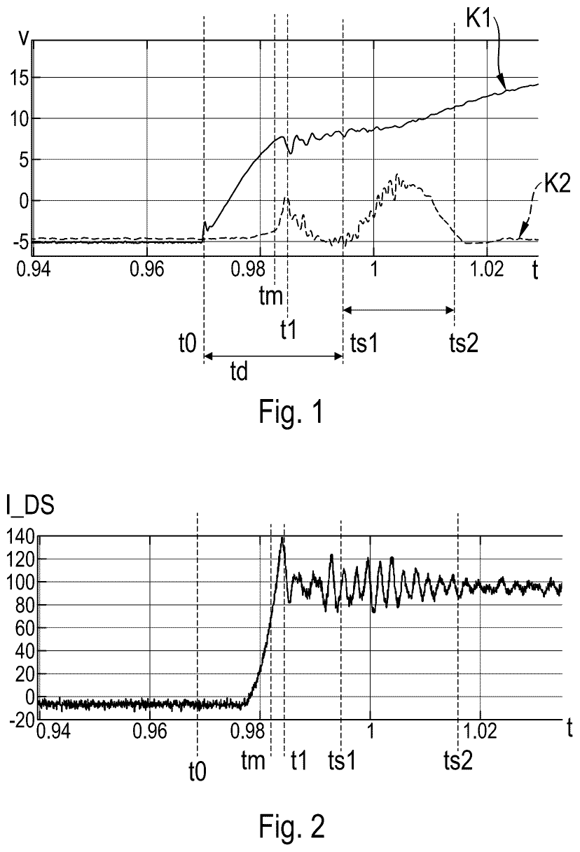

FIG. 1 shows test measurements (double pulse test of a commutation cell) of the gate voltage at two switches over time with the curves K1 (active switch, in this case the low-side switch) and K2 (passive switch, in this case the high-side switch). FIG. 2 shows a drain current for the active switch (curve K1 in FIG. 1) over time. FIG. 1 shows that high-frequency oscillations occur shortly after starting (drain current in FIG. 2 increases) switching (curve K1 for the active switch). The complementary switch is switched on briefly at a predefined time ts1 to damp the high-frequency oscillations. Curve K2 in FIG. 1 illustrates the voltage curve of the gate voltage for the complementary switch. The predefined time ts1, at which the complementary switch is switched on briefly, is after the time to for switching the active switch, because the high-frequency oscillations first occur thereafter (at time t1 in FIG. 1).

The brief switching on of the complementary (passive) switch at time ts1 after a predefined interval td after starting the switching process for the active switch at time t0 is shown in FIG. 1 (curve K2). It is important that the on-pulse is issued while the oscillations take place in order to damp at least some of them. The time before issuing the on-pulse is 100 ns or more (starting at t0) for numerous applications. The time ts1 when the on-pulse is applied to the complementary switch corresponds to the time t1 in an advantageous design, at which the oscillations begin after starting the switching process (at time t0) for the active switch. This means in general that the on-pulse can first occur when the oscillations begin (at time ts1=t1), but no earlier.

The switching process normally results in a Miller effect (after time tm in FIG. 1). This results in an increase in the gate voltage at the passive switch shortly after starting (time tm) the switching process (time t0) for the active switch, as indicated by curve K2. The oscillations that need to be compensated for occur shortly thereafter. This increase caused by the Miller effect should be detected by a driver, in order to be able to distinguish the Miller effect from the on-pulse. The on-pulse can then be issued shortly after, or at the same time as the Miller effect.

FIG. 1 shows that the complementary switch (curve K2) is not fully switched on (the voltage is below 5V), but only receives an on-pulse for a predefined time period ts1-ts2, with which it is not fully switched on, i.e. the channel is not fully opened, such that not all of the operating current can flow through the switch. If the passive switch were on for any longer, the battery would short circuit (at the intermediate circuit capacitor), which cannot happen. The on-signal for the passive switch (curve K1 in this case) must be limited because of this.

Before the complementary switch becomes saturated, and causes a short circuit through both the high-side and low-side switches, it is switched off (time ts2). The time from ts1 to ts2, when this takes place, depends on the components in the commutation cell and can be determined in tests or simulations. A rule of thumb is that the slower the switching process, the longer the passive switch stays on. With a classic B6 traction converter with SiC semiconductors, the length of the on-pulse is between 50 ns and 400 ns, in particular between 100 ns and 200 ns.

As a result of briefly switching the complementary switch on after switching the active switch-regardless of whether it is switched on or off-electricity in the switching circuit from the leakage inductance in the commutation cell and the output capacity of the switch is eliminated in the complementary switch (transistor). This also removes the output capacity of the commutation circuit, and the resistance of the conductive channel in the complementary switch is added thereto. This results in a damping of the high-frequency oscillations.

The proposed method can be used when switching on or off, or after each switching (i.e. after switching on or off). The principle, of issuing an on-pulse to the complimentary switch, remains the same. The on-pulse is issued after the active switch is switched on or off, no earlier than at time t1, when the oscillations take place. The on-pulse is maintained for a predefined period ts1 to ts2, which is usually between 100 ns and 200 ns.

To be able to at least briefly switch on both switches at the same time, it may be necessary to overwrite an existing interlocking circuit in the driver module. This provided for, or taken into account, in the design of the circuit assembly. By allowing both switches to be switched on briefly, short circuits can be prevented.

A damping of the oscillations generated by the switching process, which result from a resonance in the components in the commutation cell (leakage inductance in the commutation cell oscillates with the output capacity of the commutation circuit), is obtained with the proposed method without any additional components directly at the source. Because there is no need for additional components such as filters, there are no additional costs, and there is no need for additional installation space. By reducing the oscillations directly at the power semiconductors with this method, spreading of oscillations in the drive system after switching the semiconductors is prevented. In the low voltage range, the wiring and housing components are “cleaner” with regard to electromagnetic interference, and no high-frequency interference is emitted into the environment.

A circuit assembly for power semiconductors in an inverter that has at least one phase has a high-side switch and a low-side switch, each of which has at least one transistor. High-side switches and low-side switches are complementary to one another and switched alternatingly, such that one is the active switch and the other is the passive switch in a switching process. It does not matter which of the switches is active, because the principle of the present disclosure is the same for both types of switch. Only one of the switches in this circuit assembly for the power semiconductors can be switched on by a driver at a time, while the other remains passive (off). Both switches have at least one driver for their at least one transistor.

A highly efficient inverter, which can be used as a drive inverter or traction converter, can be obtained with the proposed method, i.e. applying an on-pulse to the complementary switch after a switching process. The circuit assembly for which the method is proposed can be used in an inverter in the electronics module for controlling the electric drive in a vehicle equipped with an electric drive.

An electronics module in the framework of this present disclosure is used to operate the electric drive in a vehicle, in particular an electric vehicle or hybrid vehicle, or in electrified axles. The electronics module contains a DC/AC inverter. It can also contain an AC/DC rectifier, a DC/DC converter, a transformer, and/or some other electrical converter or part thereof, or it can be a part thereof. Specifically, the electronics module supplies electricity to an electric machine, e.g. an electric motor and/or a generator. A DC/AC inverter is preferably used to generate a multi-phase alternating current from a direct current provided by a battery.

### LIST OF REFERENCE SYMBOLS

t0 starting of the switching process
tm start of the Miller effect
t1 start of oscillations
ts1 start of on-pulse
ts2 end of on-pulse
td length of time from t0 to ts1
K1 voltage curve for the active switch
K2 voltage curve for the complementary switch (gate voltage)

1. A method for controlling a circuit assembly for power semiconductors in an inverter that has at least one phase, containing at least two switches that are complementary to each other, which are activated alternatingly in a switching process, wherein, in the switching process, at least one of the at least two switches is an active switch and another of the at least two switches is a complementary switch, the method comprising:
applying an on-pulse to the complementary switch for a predefined period of time at a predefined time after starting the switching process for the active switch.

2. The method according to claim 1, comprising:
selecting the time at which the on-pulse is issued such that the on-pulse is applied no earlier than a time at which high-frequency oscillations first occur in a voltage and current of the active switch due to the switching process.

3. The method according to claim 2,
wherein the time after which the on-pulse is applied to the complementary switch is 100 ns or more after starting the switching process.

4. The method according to claim 1,
wherein a length of the on-pulse is such that the complementary switch does not become fully saturated.

5. The method according to claim 4,
wherein the length of the on-pulse is 50 ns to 400 ns.

6. A non-transitory computer readable medium having stored thereon a computer program that, when executed by a control unit for a vehicle, causes the control unit to perform the method according to claim 1.

7. A circuit assembly comprising:
at least one high-side switch and at least one low-side switch, each of which comprises at least one transistor,
wherein the circuit assembly is part of an inverter in an electronics module for controlling an electric drive in a vehicle equipped with the electric drive,
wherein the at least one high-side switch and the at least one low-side switch are configured to be activated alternatingly in a switching process, wherein, in the switching process, at least one of the at least one high-side switch or the at least one low-side switch is an active switch and another is a complementary switch, and
wherein the circuit assembly is configured to apply an on-pulse to the complementary switch for a predefined period of time at a predefined time after starting the switching process for the active switch.

8. The circuit assembly according to claim 7, comprising:
wherein the time at which the on-pulse is issued is selected such that the on-pulse is applied no earlier than a time at which high-frequency oscillations first occur in a voltage and current of the active switch due to the switching process.

9. The circuit assembly according to claim 8,
wherein the time after which the on-pulse is applied to the complementary switch is 100 ns or more after starting the switching process.

10. The circuit assembly according to claim 7,
wherein a length of the on-pulse is such that the complementary switch does not become fully saturated.

11. The circuit assembly according to claim 10,
wherein the length of the on-pulse is 50 ns to 400 ns.

12. An electric drive for a vehicle comprising:
an electronics module configured to control an electric drive,
wherein the electronics module comprises an inverter with the circuit assembly according to claim 7.

13. A control unit configured to control a circuit assembly that contains at least one high-side switch and at least one low-side switch, each of which has at least one transistor,
wherein the control unit is configured to:
activate the at least one high-side switch and the at least one low-side switch alternatingly in a switching process, wherein, in the switching process, at least one of the at least one high-side switch or the at least one low-side switch is an active switch and another is a complementary switch; and
apply an on-pulse to the complementary switch for a predefined period of time at a predefined time after starting the switching process for the active switch.

14. A vehicle comprising:
the control unit according to claim 13.
